(19) United States
(12) Patent Application Publication
(10) Pub. No.: US 2025/0385108 A1
(43) Pub. Date: Dec. 18, 2025

(54) METHOD OF MANUFACTURING SEMICONDUCTOR DEVICE

(71) Applicant: Kioxia Corporation, Tokyo (JP)

(72) Inventor: Wu LI, Yokkaichi Mie (JP)

(21) Appl. No.: 19/046,147

(22) Filed: Feb. 5, 2025

(30) Foreign Application Priority Data
Jun. 18, 2024 (JP) 2024-098310

(51) Int. Cl. H01L 21/67; H01J 37/32; H01L 21/3065; H10B 41/27; H10B 43/27

(52) U.S. Cl. CPC H01L 21/67069; H01J 37/32082; H01J 37/32449; H01L 21/3065; H01J 2237/2001; H01J 2237/3341; H10B 41/27; H10B 43/27

(57) ABSTRACT

According to one embodiment, a method of manufacturing a semiconductor device using a semiconductor manufacturing apparatus, includes: forming a surface layer on a recess portion of a processing target object, by supplying a first gas onto the processing target object while cooling the processing target object and without applying a high-frequency voltage to a processing chamber of the semiconductor manufacturing apparatus, wherein the first gas contains no halogens; and etching the processing target object by supplying a second gas onto the processing target object while applying the high-frequency voltage to the processing chamber, wherein the second gas contains a halogen.

### CROSS-REFERENCE TO RELATED APPLICATION

This application is based upon and claims the benefit of priority from Japanese Patent Application No. 2024-098310, filed Jun. 18, 2024, the entire contents of which are incorporated herein by reference.

### FIELD

Embodiments described herein relate generally to a method of manufacturing a semiconductor device.

### BACKGROUND

In the manufacturing of semiconductor devices such as a three-dimensional semiconductor memory, a recess portion may be formed in a processing target object through etching. When forming the recess portion, side walls of the recess portion may be protected by a protective film.

### BRIEF DESCRIPTION OF THE DRAWINGS

FIG. 1 is a diagram illustrating an example of a configuration of a semiconductor manufacturing apparatus that can be used in a method of manufacturing a semiconductor device according to a first embodiment.

FIG. 2 is a flowchart illustrating the method of manufacturing the semiconductor device according to the first embodiment.

FIG. 3 is a cross-sectional view illustrating the method of manufacturing the semiconductor device according to the first embodiment.

FIG. 4 is a timing diagram illustrating the method of manufacturing the semiconductor device according to the first embodiment.

FIG. 5 is a diagram illustrating an example of a first gas and a second gas in the method of manufacturing the semiconductor device according to the first embodiment.

FIGS. 6A and 6B are cross-sectional views illustrating the method of manufacturing the semiconductor device according to the first embodiment, subsequently to FIG. 3.

FIGS. 7A and 7B are cross-sectional views illustrating the method of manufacturing the semiconductor device according to the first embodiment, subsequently to FIGS. 6A and 6B.

FIG. 8 is a cross-sectional view illustrating the method of manufacturing the semiconductor device according to the first embodiment, subsequently to FIGS. 7A and 7B.

FIG. 9 is a flowchart illustrating a method of manufacturing a semiconductor device according to a second embodiment.

FIG. 10 is a timing diagram illustrating the method of manufacturing the semiconductor device according to the second embodiment.

FIGS. 11A and 11B are cross-sectional views illustrating the method of manufacturing the semiconductor device according to the second embodiment.

FIG. 12 is a cross-sectional view illustrating the method of manufacturing the semiconductor device according to the second embodiment, subsequently to FIGS. 11A and 11B.

FIG. 13 is a flowchart illustrating a method of manufacturing a semiconductor device according to a third embodiment.

FIG. 14 is a timing diagram illustrating the method of manufacturing the semiconductor device according to the third embodiment.

FIGS. 15A and 15B are cross-sectional views illustrating the method of manufacturing the semiconductor device according to the third embodiment.

FIG. 16 is a cross-sectional view illustrating the method of manufacturing the semiconductor device according to the third embodiment, subsequently to FIGS. 15A and 15B.

FIGS. 17A and 17B are cross-sectional views illustrating a method of manufacturing a semiconductor device according to a fourth embodiment.

FIGS. 18A and 18B are cross-sectional views illustrating the method of manufacturing the semiconductor device according to the fourth embodiment, subsequently to FIGS. 17A and 17B.

### DETAILED DESCRIPTION

Embodiments provide a method of manufacturing a semiconductor device capable of appropriately etching a processing target object.

In general, according to one embodiment, a method of manufacturing a semiconductor device using a semiconductor manufacturing apparatus, includes: forming a surface layer on a recess portion of a processing target object, by supplying a first gas onto the processing target object while cooling the processing target object and without applying a high-frequency voltage to a processing chamber of the semiconductor manufacturing apparatus, wherein the first gas contains no halogens; and etching the processing target object by supplying a second gas onto the processing target object while applying the high-frequency voltage to the processing chamber, wherein the second gas contains a halogen.

Embodiments will be described below with reference to the drawings. In order to facilitate understanding of the description, identical components in each drawing are represented by the same reference numerals and signs as much as possible, and duplicated descriptions will not be repeated.

### First Embodiment

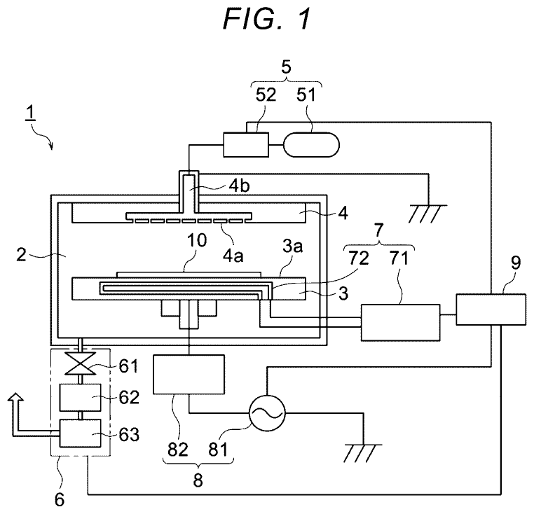

FIG. 1 is a diagram illustrating an example of the configuration of a semiconductor manufacturing apparatus 1 that can be used in a method of manufacturing a semiconductor device according to a first embodiment. As illustrated in FIG. 1, the semiconductor manufacturing apparatus 1 includes a processing chamber 2, a lower electrode 3, an upper electrode 4, a gas supply device 5, a gas discharge device 6, a cooling device 7, a power supply device 8, and a control circuit 9.

The processing chamber 2 is a room in which a processing target object 10 can be subjected to etching (for example, plasma etching) through sputtering using plasma. In the processing chamber 2, a hole (for example, a recess portion) is formed in the processing target object 10 through etching. The hole may also be referred to as an opening. The processing chamber 2 may have a door (gate) for loading and unloading the processing target object 10.

The lower electrode 3 functions as a loading table for loading the processing target object 10. The lower electrode 3 has a surface 3a on which the processing target object 10 is loaded. The semiconductor manufacturing apparatus 1 may have an electrostatic chuck for holding the processing target object 10 on the surface 3a.

The upper electrode 4 has a surface 4a and an opening 4b for introducing gas into the processing chamber 2 through the upper electrode 4. The opening 4b has a plurality of inlet ports on the surface 4a.

The gas supply device 5 has a gas supply source 51 such as a cylinder cabinet and a mass flow controller 52. The gas supply device 5 supplies gas from the gas supply source 51 to the processing chamber 2.

The gas supply source 51 contains a first gas, a second gas, and a third gas. For example, the gas supply source 51 may be a container such as a gas cylinder.

The first gas is a gas used to form a surface layer on the surface of the processing target object 10. The first gas is a gas that does not contain any halogens. The first gas may be, for example, an inorganic gas that does not contain any halogens. The inorganic gas that does not contain any halogens may be, for example, water vapor or hydrogen peroxide. The organic gas that does not contain any halogens may be, for example, an organic solvent gas. Examples of the organic gas that does not contain any halogens include at least one of the compounds represented by R—OH, R—CHO, R—COOH, R—NO₂, R—NH₂, R1-OCO—R2, R—CN, R1-O—R2, or an organic gas represented by a composition formula CxHy (x and y are each integers). Specifically, the organic gas that does not contain halogen may include at least one of C₇H₁₄O₂ (butyl propionate), C₃H₄O (acrolein: 2-propenal), C₃H₃N (acrylonitrile: propenenitrile), C₇H₁₀O₃ (allyl acetoacetate), C₃H₆O (allyl alcohol: 2-propen-1-ol), C₈H₁₄ (allyl cyclopentane), C₇H₈O (anisole methoxybenzene), C₈H₁₂ (1,4-cyclooctadiene), C₈H₁₂ (cis,cis-1,5-cyclooctadiene), C₈H₁₀ (1,3,5-cyclooctatriene), and C₈H₁₈O (dibutyl ether).

The second gas is a gas used for etching the processing target object 10 on which the surface layer is formed. The second gas is a gas that contains a halogen. The second gas may be, for example, a gas that contains fluorine as the halogen. The second gas is a gas that has a lower condensation temperature than the first gas. That is, the first gas is a gas that has a higher condensation temperature than the second gas. The second gas is, for example, a fluoride gas represented by a composition formula CxHyFz (where C represents carbon, H represents hydrogen, F represents fluorine, x represents an integer of 0 or more, y represents an integer of 0 or more, and z represents an integer of 1 or more). The second gas may be HF gas. The second gas may further contain fluoride gases, such as SiF₄ and PF₃, different from the composition formula CxHyFz.

The third gas is a gas that is used in etching to remove a surface layer which is formed on the bottom surface of a hole of the processing target object 10. The third gas is, for example, a rare gas such as Ar gas.

The mass flow controller 52 adjusts a flow rate of the first gas, a flow rate of the second gas, and a flow rate of the third gas introduced from the gas supply source 51 into the processing chamber 2.

The gas discharge device 6 has a valve 61, a turbo molecular pump 62, and a dry pump 63. The gas discharge device 6 depressurizes the inside of the processing chamber 2. The gas discharge device 6 is able to depressurize the inside of the processing chamber 2 to a vacuum state. The gas discharge device 6 also discharges the gas inside the processing chamber 2.

The cooling device 7 has a chiller 71 and a refrigerant tube 72 provided inside the lower electrode 3. The chiller 71 cools the processing target object 10 on the lower electrode 3 by circulating a refrigerant through the refrigerant tube 72. The power supply device 8 has a power supply 81 that applies an AC voltage and a matching circuit 82 such as a matching box. The power supply device 8 applies a high-frequency voltage, e.g., with a radio frequency (RF), to the processing chamber 2 by matching the impedance between the processing chamber 2 and the power supply 81 using the matching circuit 82. The high-frequency voltage may be, for example, an AC voltage having a frequency of 200 kHz or more and 200 MHz or less.

The control circuit 9 controls the mass flow controller 52, the power supply 81, the gas discharge device 6, and the cooling device 7. The control circuit 9 is configured with hardware such as a processor. A program for executing the processing of the control circuit 9 may be stored in a recording medium such as a memory device, e.g., random-access memory (RAM), and the control circuit 9 may execute the processing by reading and executing the program stored in the recording medium.

Next, the method of manufacturing the semiconductor device according to the first embodiment, to which the semiconductor manufacturing apparatus 1 configured as above is applied, will be described.

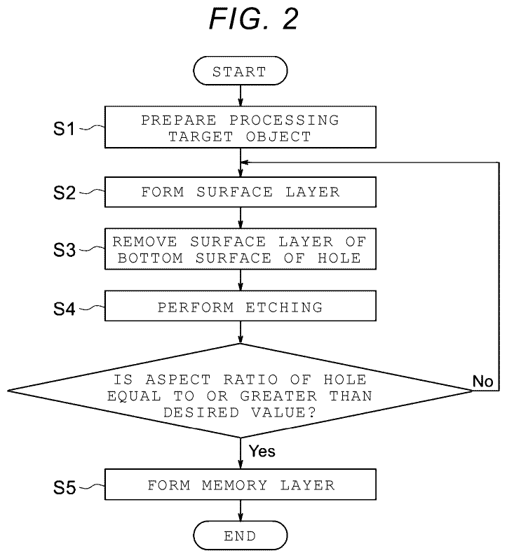

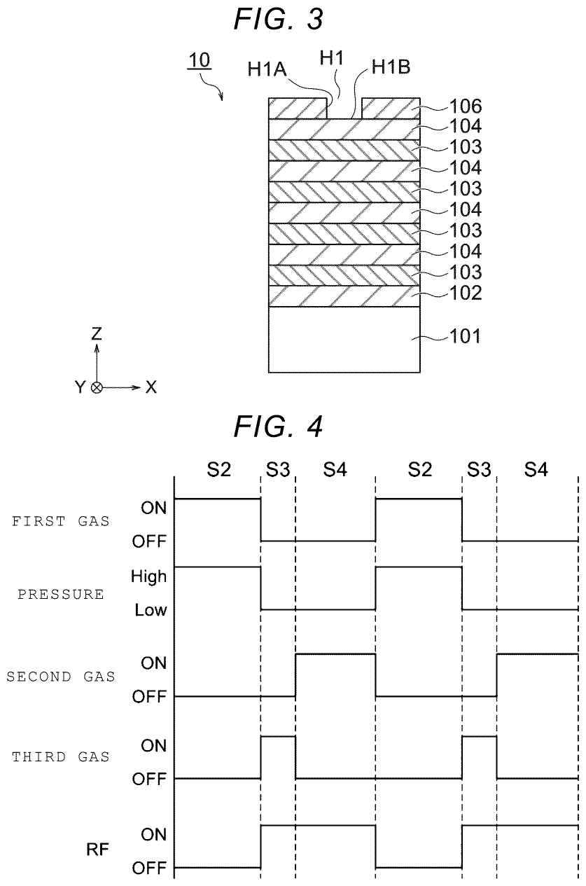

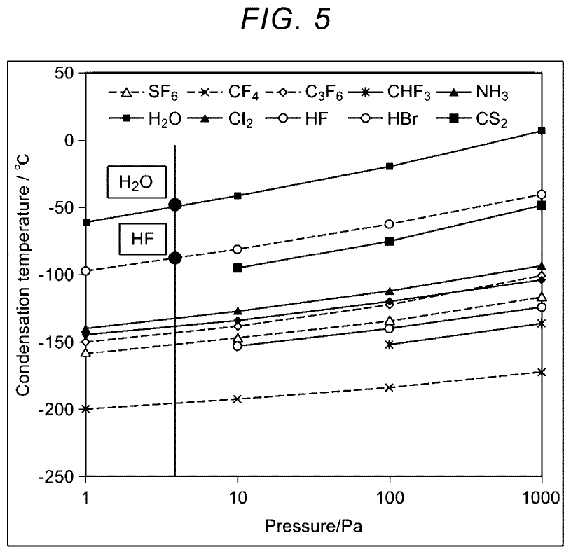

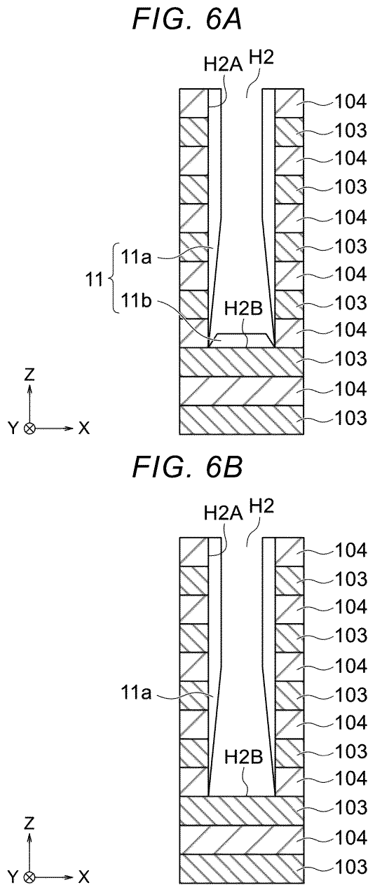

FIG. 2 is a flowchart illustrating the method of manufacturing the semiconductor device according to the first embodiment. FIG. 3 is a cross-sectional view illustrating the method of manufacturing the semiconductor device according to the first embodiment. Specifically, FIG. 3 illustrates a part of an X-Z cross section including an X axis along a surface of a substrate 101 and a Z axis perpendicular to the X axis along a thickness direction of the substrate 101. FIG. 4 is a timing diagram illustrating the method of manufacturing the semiconductor device according to the first embodiment. FIG. 5 is a diagram illustrating an example of a first gas and a second gas in the method of manufacturing the semiconductor device according to the first embodiment. FIGS. 6A and 6B are cross-sectional views illustrating the method of manufacturing the semiconductor device according to the first embodiment, subsequently to FIG. 3.

As illustrated in FIG. 2, first, the processing target object 10 is prepared (step S1). Specifically, the processing target object 10 having the configuration illustrated in FIG. 3 is formed.

As illustrated in FIG. 3, the processing target object 10 includes the substrate 101, an under layer 102 provided on the substrate 101, a stacked film 103, 104 having first layers 103 and second layers 104 alternately stacked on the under layer 102, and a mask layer 106 provided on the stacked film 103, 104. The mask layer 106 is provided with an opening portion H1 that penetrates the mask layer 106 and that has a side wall H1A and a bottom surface H1B.

The substrate 101 may be, for example, a semiconductor substrate such as a silicon substrate or a silicon carbide substrate, an insulating substrate such as a glass substrate, a quartz substrate, or a sapphire substrate, or a compound semiconductor substrate such as a GaAs substrate.

The under layer 102 may be, for example, an insulating film such as a silicon oxide film or a silicon nitride film, or a conductive layer between insulating films. According to some embodiments, the under layer 102 may be omitted. When the under layer 102 is not provided, a first layer 103 or second layer 104 is formed directly on the substrate 101.

In the example illustrated in FIG. 3, the first layer 103 is a sacrifice layer. The sacrifice layer is a region in which a conductive layer is to be formed later. That is, the sacrifice layer is a layer that is removed between second layers 104 through wet etching using a chemical solution such as phosphoric acid, to be replaced with the conductive layer. Each first layer 103 may be, for example, a silicon nitride film.

Each second layer 104 may be, for example, a silicon oxide film.

The mask layer 106 functions as a mask for etching the processing target object 10. The mask layer 106 may be, for example, a carbon film that is formed by a chemical vapor deposition (CVD) method.

After providing the processing target object 10, a hole H2 is formed in the processing target object 10 through first etching (not illustrated in FIG. 3) using the mask layer 106, which is continuous from the opening portion H1 downward (in the −Z direction) (FIGS. 6A and 6B). It should be noted that the hole H2 illustrated in FIGS. 6A and 6B is the hole H2 after processing has progressed through multiple etchings (multiple iterations of step S4). In a step where the hole H2 is first formed through a first etching, a depth of the hole H2 is shallow. After the hole H2 is formed, as illustrated in FIG. 2, a surface layer 11 may be formed on the processing target object 10 where the hole H2 is formed (step S2, FIG. 6A). The surface layer 11 may also be formed on another inner surface (for example, side wall H1A) of the mask layer 106 before or during the first etching in which the hole H2 is formed.

As illustrated in FIG. 4, in the process of forming the surface layer 11 (step S2), the control circuit 9 controls the mass flow controller 52 such that the mass flow controller 52 introduces the first gas into the processing chamber 2 (first gas: ON in FIG. 4). In the process of forming the surface layer 11 (step S2), the control circuit 9 does not cause the power supply 81 to apply a high-frequency voltage to the processing chamber 2 (RF: OFF in FIG. 4). The control circuit 9 controls the cooling device 7 such that the cooling device 7 may cool the processing target object 10 to a temperature equal to or lower than the condensation temperature of the first gas and equal to or higher than the condensation temperature of the second gas. Alternatively, the control circuit 9 may cause the cooling device 7 to cool the processing target object 10 to a temperature equal to or lower than the triple point temperature of the first gas and equal to or higher than the triple point temperature of the second gas. The control circuit 9 may cause the cooling device 7 to cool the processing target object 10 to a temperature equal to or lower than a melting point of the first gas and equal to or higher than a melting point of the second gas. For example, the control circuit 9 may cause the cooling device 7 to cool the processing target object 10 to within a range of −20° C. to −130° C. Such cooling of the processing target object 10 is continued in an etching process (step S4) after the process of forming the surface layer 11 (step S2). Therefore, in the first embodiment, the etching of the processing target object 10 is performed with the processing target object 10 cooled. The control circuit 9 controls the gas discharge device 6. Thereby, the gas discharge device 6 performs control such that a pressure in the processing chamber 2 is higher than the pressure during etching of the processing target object 10 (pressure: High in FIG. 4).

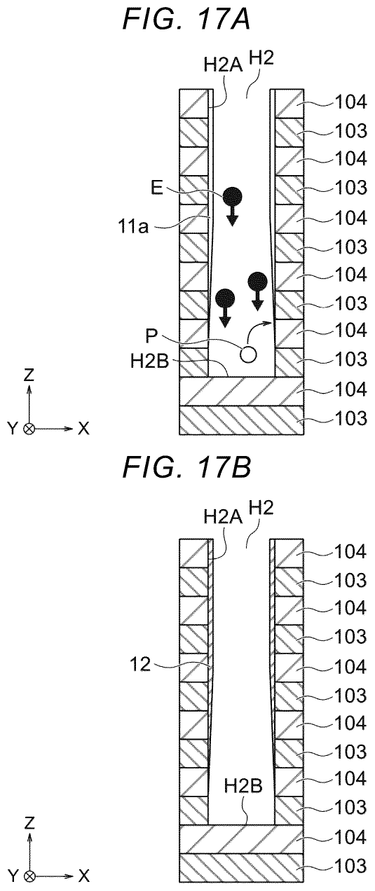

Under such control performed by the control circuit 9, the first gas not containing any halogens is supplied onto the processing target object 10 without applying a high-frequency voltage, the processing target object 10 is cooled, and in such a state, the surface layer 11 containing the first gas is formed on the surface of the processing target object 10. Specifically, it is preferable that the surface layer 11 is formed on the surface of the processing target object 10 in a state where the processing target object 10 is cooled to a temperature equal to or lower than the condensation temperature of the first gas and equal to or higher than the condensation temperature of the second gas. More specifically, it is preferable that the surface layer 11 is formed on the surface of the processing target object 10 under a pressure higher than the pressure during etching of the processing target object 10. As illustrated in FIG. 5, for example, at a particular pressure, the condensation temperature of the first gas is −50° C. when the first gas is water (H₂O) such as water vapor or H₂O gas, and the condensation temperature of the second gas is −80° C. when the second gas is hydrogen fluoride (HF). In such a case, it is preferable to form the surface layer 11 in a state where the processing target object 10 is cooled to a temperature of −80° C. or higher and −50° C. or lower. It should be noted that FIG. 5 is based on a description in the Journal of Vacuum Science & Technology A (Feb. 27, 2023, “Condensation temperatures of gases relevant for semiconductor etching,” Values from Ref. 146, p14, FIG. 17).

The process of forming the surface layer 11 (step S2) will be described in more detail. As illustrated in FIGS. 6A and 6B, the etching of the processing target object 10 is performed to increase the depth of the hole H2 which is formed in the processing target object 10 by repeating the etching. FIG. 6A illustrates the process of forming the surface layer 11 in the hole H2 after the etching of the processing target object 10 is repeated multiple times with respect to FIG. 3. In FIG. 6A, the mask layer 106 on the stacked film 103, 104 is omitted. As illustrated in FIG. 6A, the surface layer 11 includes a surface layer 11a formed on a side wall H2A of the hole H2. Further, as illustrated in FIG. 6A, the surface layer 11 includes a surface layer 11b formed on a bottom surface H2B of the hole H2. That is, in the process of forming the surface layer 11 (step S2), the surface layer 11 is formed on both the side wall H2A and the bottom surface H2B of the hole H2.

The surface layer 11a formed on the side wall H2A of the hole H2 is able to prevent bowing from being caused by side etching, by protecting the side wall H2A during etching. In contrast, the surface layer 11b, which is formed on the bottom surface H2B of the hole H2, inhibits etching of the bottom surface H2B. As illustrated in FIG. 2, after the surface layer 11 is formed (step S2), in order to prevent the surface layer 11b formed on the bottom surface H2B of the hole H2 from inhibiting etching, the surface layer 11b, which is formed on the bottom surface H2B of the hole H2, is removed (step S3).

As illustrated in FIG. 4, in the removal process of the surface layer 11b (step S3), the control circuit 9 controls the mass flow controller 52 such that the mass flow controller 52 introduces the third gas into the processing chamber 2 instead of the first gas (first gas: OFF in FIG. 4, and third gas: ON in FIG. 4). The control circuit 9 also controls the power supply 81 such that the power supply 81 applies a high-frequency voltage to the processing chamber 2 (RF: ON in FIG. 4). The control circuit 9 also controls the gas discharge device 6. Thereby, the gas discharge device 6 performs control such that the pressure in the processing chamber 2 is lower than the pressure during forming of the surface layer 11 (pressure: Low in FIG. 4).

Under such control performed by the control circuit 9, the third gas is supplied while a high-frequency voltage is applied to the processing target object 10, and the surface layer 11b, which is formed on the bottom surface H2B of the hole H2, is removed by performing etching with plasma generated from the third gas (FIG. 6B). When the surface layer 11b formed on the bottom surface H2B of the hole H2 is removed, the surface layer 11a formed on the side wall H2A protects the side wall H2A of the hole H2.

After the surface layer 11b formed on the bottom surface H2B of the hole H2 is removed, the processing target object 10 is etched as illustrated in FIG. 2 (step S4). The hole H2 formed in the processing target object 10 is processed (made deeper) by etching the processing target object 10. The etching of the processing target object 10 is performed on the bottom surface H2B of the hole H2 while the surface layer 11a formed on the side wall H2A of the hole H2 protects the side wall H2A. As illustrated in FIG. 4, in the etching process (step S4) of the processing target object 10, the control circuit 9 controls the mass flow controller 52 such that the mass flow controller 52 introduces the second gas into the processing chamber 2 instead of the third gas (third gas: OFF in FIG. 4, and second gas: ON in FIG. 4). The control circuit 9 also controls the power supply 81 such that the power supply 81 continues to apply a high-frequency voltage to the processing chamber 2 (RF: ON in FIG. 4). The control circuit 9 also keeps the pressure in the processing chamber 2 lower than that when the surface layer 11 is formed (pressure: Low).

Under such control performed by the control circuit 9, the second gas is supplied onto the processing target object 10 while the high-frequency voltage is applied, and the processing target object 10 is etched using plasma generated from the second gas.

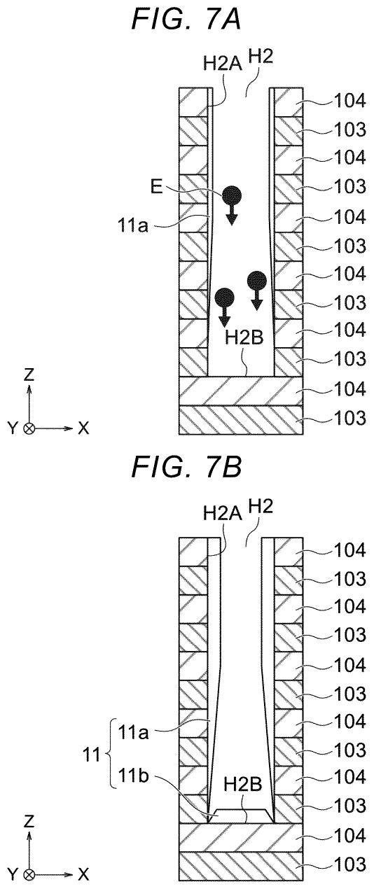

FIGS. 7A and 7B are cross-sectional views illustrating the method of manufacturing the semiconductor device according to the first embodiment, subsequently to FIGS. 6A and 6B. In the example illustrated in FIGS. 7A and 7B, the processing target object 10 is etched by an etchant E (for example, ions and radicals) in the plasma generated from the second gas. As illustrated in

FIGS. 7A and 7B, in the etching process of the processing target object 10, the surface layer 11a protects the side wall H2A of the hole H2. That is, the surface layer 11a on the side wall H2A is etched, instead of etching the side wall H2A of the hole H2. Meanwhile, as mentioned previously, the surface layer 11b on the bottom surface H2B of the hole H2 is removed through the removal process (step S3). Therefore, the etching in the hole H2 proceeds in the depth direction (−Z direction) of the hole H2 while preventing side etching (for example, bowing) from being performed. In the example illustrated in FIG. 7A, only an uppermost first layer 103 that had not yet been etched (refer to FIGS. 6A and 6B) is removed through one etching of the processing target object 10. In practice, however, a plurality of the first layers 103 and a plurality of the second layers 104 may be removed through one etching of the processing target object 10.

After the etching of the processing target object 10, the formation of the surface layer 11 is repeated as illustrated in FIG. 7B.

As illustrated in FIG. 2, the formation of the surface layer 11 (step S2), the removal of the surface layer 11b formed on the bottom surface H2B of the hole H2 (step S3), and the etching of the processing target object 10 (step S4) are sequentially repeated until an aspect ratio of the hole H2 is equal to or greater than a desired value. The aspect ratio of the hole H2 is a ratio of the dimension (for example, height) of the hole H2 in the Z direction to the dimension (for example, width) of the hole H2 in the X direction. The aspect ratio of the hole H2 may be set to be equal to or greater than a desired value by performing the processes from steps S2 to S4 a preset number of times.

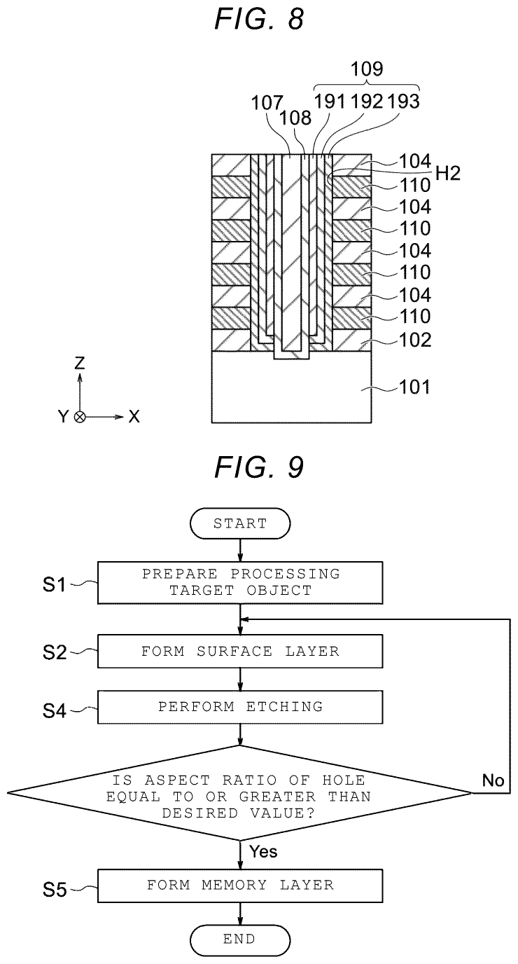

After the aspect ratio of the hole H2 is equal to or greater than the desired value, as illustrated in FIG. 2, a memory layer is formed in the hole H2 (for example, memory hole) (step S5). FIG. 8 is a cross-sectional view illustrating the method of manufacturing the semiconductor device according to the first embodiment, subsequently to FIGS. 7A and 7B. In the process of forming the memory layer (step S5), a memory film 109 including a block insulating film 193, a charge storage layer 192, and a tunnel insulating film 191, a semiconductor channel layer 108, and a core insulating film 107 are formed in this order in the hole H2. The core insulating film 107, the semiconductor channel layer 108, and the memory film 109 function as the memory layer forming a memory cell.

The core insulating film 107 may be, for example, a silicon oxide film. The semiconductor channel layer 108 may be, for example, a polysilicon layer. The tunnel insulating film 191 may be, for example, a stacked film that has a silicon oxide film and a silicon oxynitride film. The charge storage layer 192 may be, for example, a silicon nitride film. The block insulating film 193 may be, for example, a silicon oxide film.

After the memory film 109 is formed, cavities are formed between the second layers 104 by removing the first layers 103 through wet etching. After the cavities are formed, conductive layers 110 are formed by stacking a plurality of conductive films in the cavities. Each conductive layer 110 functions as, for example, a gate electrode (word line). Further, contact plugs, wiring, interlayer insulating films, and the like are formed on the substrate 101. Thereby, it is possible to manufacture the semiconductor device.

As described above, the method of manufacturing the semiconductor device according to the first embodiment includes switching alternately between forming of the surface layer 11 and etching of the processing target object 10. The surface layer 11, which contains the first gas not containing any halogens, is formed on a surface of the processing target object 10, on which the hole H2 (for example, the recess portion) is formed, by supplying the first gas onto the processing target object 10 without applying a high-frequency voltage to the processing target object 10 and by cooling the processing target object 10. The processing target object 10 is etched with plasma generated from the second gas, which contains the halogen, to process the hole H2 by supplying the second gas onto the processing target object 10 while applying the high-frequency voltage to the processing target object 10. In other words, the method of manufacturing the semiconductor device according to the first embodiment includes switching alternately between the etching of the processing target object 10 and forming of the surface layer 11. Regarding the etching of the processing target object 10, the second gas containing a halogen is supplied onto the processing target object 10 while a high-frequency voltage is applied, and the processing target object 10 is etched using plasma generated from the second gas to form the hole H2. Regarding the forming of the surface layer 11, the first gas not containing any halogens is supplied onto the processing target object 10 in which the hole H2 is formed without applying the high-frequency voltage, and the surface layer 11 containing the first gas is formed on the surface of the processing target object 10. That is, the method of manufacturing the semiconductor device according to the first embodiment alternately switches between forming of the surface layer 11 and processing of the hole H2 performed through etching.

Here, when the processing target object 10 is etched (for example, cryogenic etching) in a state where the cooling device 7 cools the processing target object 10 as described above, an etching rate can be improved. However, when the processing target object 10 is etched in a state where the processing target object 10 is cooled, it may be difficult to form a protective film to protect the side wall H2A due to the chemical reaction of the etching gas. When the protective film is difficult to form due to the chemical reaction of the etching gas, it is difficult to protect the side wall H2A with the protective film. Since it is difficult to protect the side wall H2A, it is difficult to prevent bowing.

In contrast, according to the first embodiment, the surface layer 11 can be formed before etching. Therefore, the surface layer 11a formed on the side wall H2A is able to appropriately protect the side wall H2A. Therefore, even when the processing target object 10 is cooled to improve the etching rate, the side wall H2A can be protected and bowing can be prevented. Further, by using a gas that does not contain halogen as the first gas used to form the surface layer 11, it is possible to reduce the effect on the film formation conditions, such as changes in the etching conditions caused by the residual gas of the first gas. Furthermore, if the surface layer 11 were formed by using a gas containing a halogen as the first gas, then ions in the first gas would collide with the side wall H2A, and the processing target object 10 to be protected would react with the excess halogen contained in the first gas. Thus, bowing would be likely to be formed. However, by forming the surface layer 11 using the first gas that does not contain any halogens, it is possible to effectively prevent bowing.

In the first embodiment, it is preferable that the first gas has a higher condensation temperature than the second gas. Thereby, it is possible to easily form the surface layer 11.

In the first embodiment, it is preferable that the surface layer 11 is formed in a state where the processing target object 10 is cooled at a temperature equal to or lower than the condensation temperature of the first gas. Thereby, it is possible to rapidly form the surface layer 11. As a result, it is possible to improve the etching rate.

In the first embodiment, it is preferable that the surface layer 11 is formed in a state where the processing target object 10 is cooled at a temperature equal to or higher than the condensation temperature of the second gas. Thereby, it is possible to effectively prevent the second gas from solidifying during etching after the formation of the surface layer 11. As a result, it is possible to further improve the etching rate.

In the first embodiment, it is preferable that the surface layer 11 is formed under a pressure higher than the pressure during the etching of the processing target object 10. Thereby, by shortening the mean free path of particles in the first gas, it is possible to reduce the surface layer 11b formed on the bottom surface H2B of the hole H2. As a result, it is possible to further improve the etching rate. In the first embodiment, the surface layer 11b on the bottom surface H2B of the hole H2 is removed in the removal process (step S3 of FIG. 2). Thus, pressure control is not required.

In the first embodiment, it is preferable that the first gas is an inorganic gas that does not contain any halogens. It is preferable that the inorganic gas is water vapor or hydrogen peroxide. Thereby, it is possible to rapidly and appropriately form the surface layer 11.

In the first embodiment, it is preferable that the second gas contains a fluoride gas. Thereby, it is possible to appropriately etch the processing target object 10.

In the first embodiment, it is preferable that the processing target object 10 is etched such that the depth of the hole H2 increases as the etching is repeated, and the surface layer 11 is formed on the side wall H2A of the hole H2. Thereby, it is possible to etch the bottom surface H2B of the hole H2 at a high etching rate in a state where the side wall H2A of the hole H2 is appropriately protected.

It is preferable that the first embodiment further includes removing the surface layer 11b formed on the bottom surface H2B of the hole H2 between the formation of the surface layer 11 and the etching of the processing target object 10. Thereby, it is possible to remove the surface layer 11b of the bottom surface H2B, which would otherwise inhibit the etching. As a result, it is possible to further improve the etching rate.

In the first embodiment, it is preferable to remove the surface layer 11b formed on the bottom surface H2B of the hole H2 by performing etching with plasma generated from the third gas. Thereby, it is possible to appropriately remove the surface layer 11b of the bottom surface H2B of the hole H2.

### Second Embodiment

Next, a description will be given of a second embodiment in which the surface layer 11 is not formed on the bottom surface H2B of the hole H2, focusing on the differences from the first embodiment.

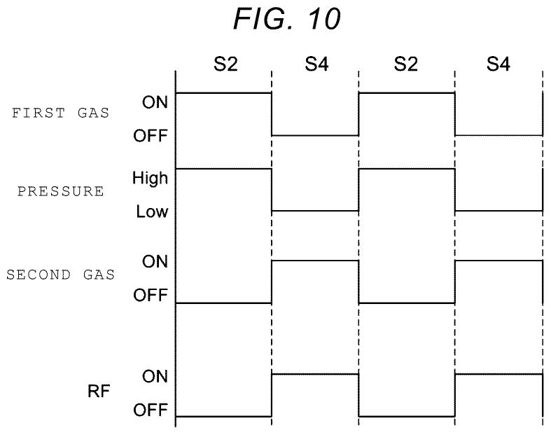

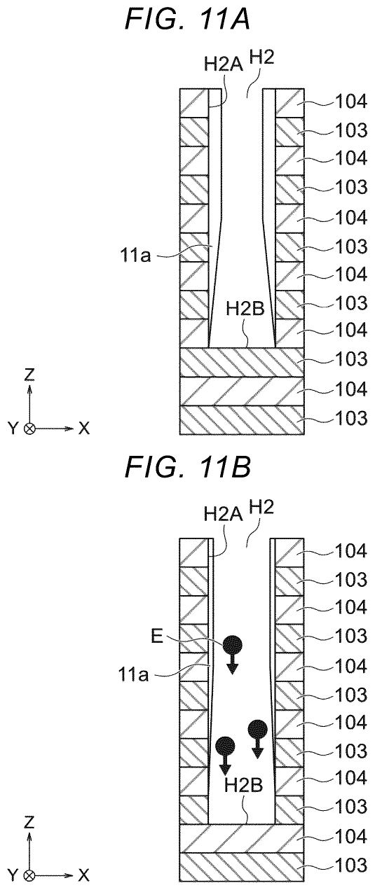

FIG. 9 is a flowchart illustrating a method of manufacturing a semiconductor device according to the second embodiment. FIG. 10 is a timing diagram illustrating the method of manufacturing the semiconductor device according to the second embodiment. FIGS. 11A and 11B are cross-sectional views illustrating the method of manufacturing the semiconductor device according to the second embodiment.

In FIG. 2, an example was described in which the surface layer 11b formed on the bottom surface H2B is removed after the surface layer 11 is formed on the side wall H2A and the bottom surface H2B of the hole H2. In contrast, in the example illustrated in FIGS. 9 to 11B, the surface layer 11 is formed on the side wall H2A of the hole H2 but not on the bottom surface H2B of the hole H2. That is, in the example illustrated in FIGS. 9 to 11B, the surface layer 11 is formed under conditions that prevent the surface layer 11b from being formed on the bottom surface H2B of the hole H2 (step S2 in FIGS. 9 and 10).

For example, the control circuit 9 may control the gas discharge device 6 such that the pressure in the processing chamber 2 is higher than the pressure thereof in the first embodiment. Thereby, the surface layer 11b is prevented from being formed on the bottom surface H2B of the hole H2. When the pressure in the processing chamber 2 is increased, the mean free path of the particles in the first gas is shortened. When the mean free path is shortened, the number of particles in the first gas that reach the bottom surface H2B of the hole H2 is reduced. Therefore, the surface layer 11b can be prevented from being formed on the bottom surface H2B. In addition to increasing the pressure in the processing chamber 2, for example, the control circuit 9 may prevent the surface layer 11b from being formed on the bottom surface H2B of the hole H2 by adjusting the flow rate of the first gas.

The surface layer 11b is not formed on the bottom surface H2B of the hole H2. Therefore, in the examples illustrated in FIGS. 9 to 11B, the process of removing the surface layer 11b formed on the bottom surface H2B is not necessary. Therefore, in the examples illustrated in FIGS. 9 to 11B, etching is performed (step S4 in FIGS. 9 and 10, and FIG. 11B) immediately after the formation of the surface layer 11 (step S2 in FIGS. 9 and 10, and FIG. 11A).

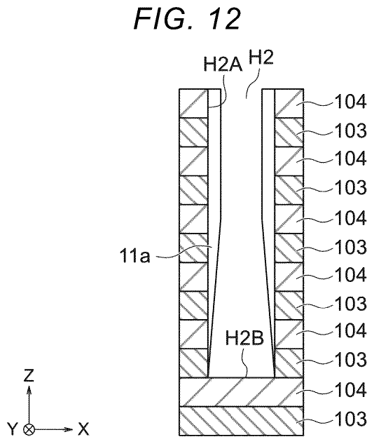

FIG. 12 is a cross-sectional view illustrating the method of manufacturing the semiconductor device according to the second embodiment, subsequently to FIGS. 11A and 11B. After the processing target object 10 is etched, as illustrated in FIG. 12, the surface layer 11 is repeatedly formed on the processing target object 10 with the hole H2 without being formed on the bottom surface H2B of the host H2, and the depth of the hole H2 is increased.

As described above, in the second embodiment, the surface layer 11 is formed on the side wall H2A of the hole H2 without being formed on the bottom surface H2B of the hole H2. Thereby, it is possible to omit the process of removing the surface layer 11b on the bottom surface H2B. As a result, it is possible to further increase the etching rate.

### Third Embodiment

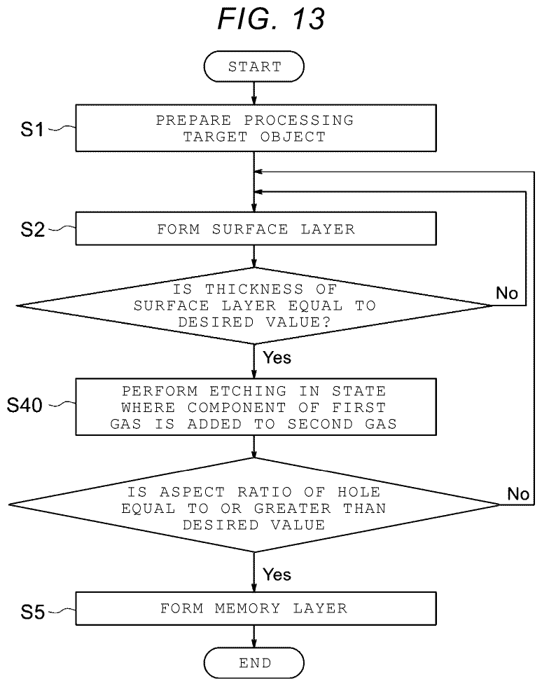

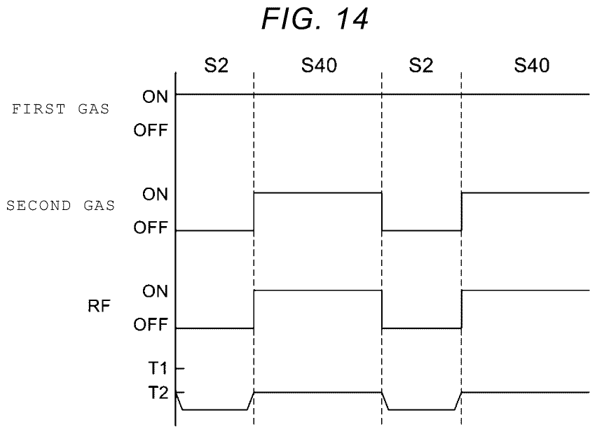

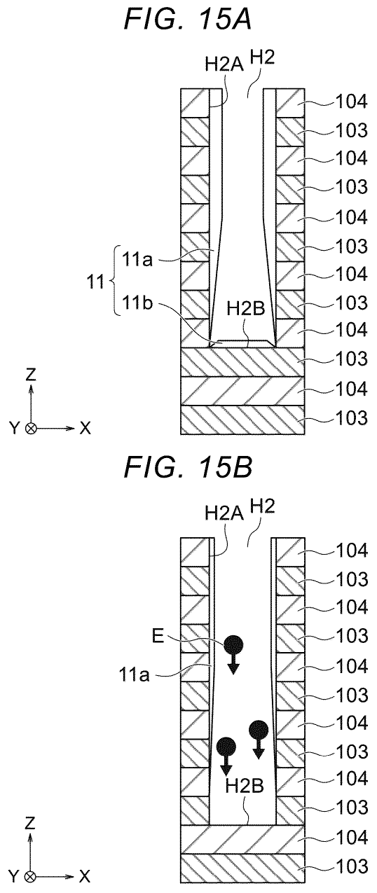

Next, a description will be given of a third embodiment in which the surface layer 11b on the bottom surface H2B of the hole H2 is used as an etchant, focusing on the differences from the first and second embodiments. FIG. 13 is a flowchart illustrating a method of manufacturing a semiconductor device according to the third embodiment. FIG. 14 is a timing diagram illustrating the method of manufacturing the semiconductor device according to the third embodiment. FIGS. 15A and 15B are cross-sectional views illustrating the method of manufacturing the semiconductor device according to the third embodiment.

In FIG. 2, an example was described in which the surface layer 11b formed on the bottom surface H2B of the hole H2 functions as an etching inhibition layer, and thus the surface layer 11b on the bottom surface H2B of the hole H2 is removed. In contrast, in the example illustrated in FIGS. 13 to 15B, the etching of the processing target object 10 is performed while the surface layer 11a formed on the side wall H2A of the hole H2 protects the side wall H2A and the surface layer 11b formed on the bottom surface H2B of the hole H2 promotes etching. That is, in the examples illustrated in FIGS. 13 to 15B, the surface layer 11a on the side wall H2A of the hole H2 is used as a protective film, and the surface layer 11b on the bottom surface H2B of the hole H2 is used as an etchant.

Specifically, in the examples illustrated in FIGS. 13 to 15B, after the surface layer 11 is formed with a desired thickness (step S2 in FIGS. 13 and 14, and FIG. 15A), the surface layer 11b on the bottom surface H2B of the hole H2 is not removed. Instead of removing the surface layer 11b on the bottom surface H2B of the hole H2, the processing target object 10 is etched in a state where the first gas is added to the second gas (step S40 in FIGS. 13 and 14, and FIG. 15B). The desired thickness of the surface layer 11 may be obtained (at a desired value) by supplying the first gas at a preset flow rate for a preset time.

More specifically, as illustrated in FIG. 14, the first gas is continuously supplied during both a period in which the surface layer 11 is formed, and a period in which the processing target object 10 is etched, through control of the mass flow controller 52 which is controlled by the control circuit 9. As illustrated in FIGS. 15A and 15B, after the surface layer 11 is formed, including on the bottom surface H2B of the hole H2, the etching process is started in a state where the surface layer 11b is on the bottom surface H2B (FIG. 15A), and then a first layer 103 is etched (FIG. 15B). As illustrated in FIG. 14, in the process of forming the surface layer 11 (step S2 in FIGS. 13 and 14), it is preferable that the control circuit 9 controls the cooling device 7 such that the processing target object 10 is cooled at a temperature lower than a triple point temperature T1 of the first gas and a triple point temperature T2 of the second gas. In the etching process (step S40 in FIGS. 13 and 14), it is preferable that the control circuit 9 controls the cooling device 7 such that the processing target object 10 is cooled at the triple point temperature T2 of the second gas. When the first gas is H₂O, the triple point temperature T1 is −50° C. at a pressure of 4 Pa. When the second gas is HF, the triple point temperature T2 is −80° C. at a pressure of 4 Pa.

For example, when the thickness of the surface layer 11b formed on the bottom surface H2B of the hole H2 is sufficiently thinner than the thickness of the surface layer 11a formed on the side wall H2A of the hole H2, the surface layer 11b is able to function as an etchant which is not an inhibition layer. For example, the control circuit 9 is able to adjust the thickness of the surface layer 11b such that the thickness of the surface layer 11b is kept at a thickness at which the surface layer 11b functions as an etchant, by adjusting the pressure in the processing chamber 2 or the amount of the supplied first gas.

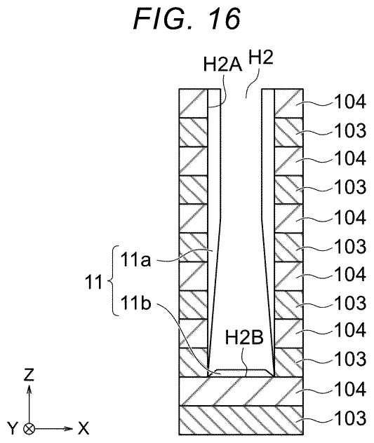

FIG. 16 is a cross-sectional view illustrating a method of manufacturing the semiconductor device according to the third embodiment, subsequently to FIGS. 15A and 15B. After the processing target object 10 is etched, as illustrated in FIG. 16, the surface layer 11 is repeatedly formed on the processing target object 10 with the hole H2 of which the depth is increased.

According to the third embodiment, the surface layer 11a formed on the side wall H2A of the hole H2 functions as a protective film, and the surface layer 11b formed on the bottom surface H2B of the hole H2 functions as an etchant. Thereby, the etching rate can be further increased while the side wall H2A is protected.

### Fourth Embodiment

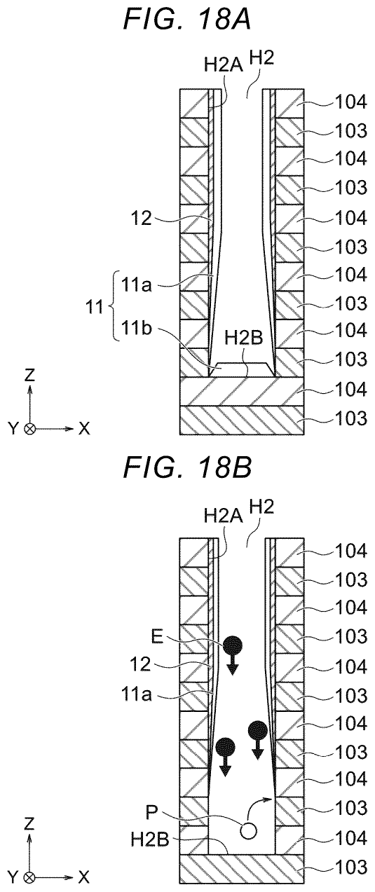

Next, a description will be given of a fourth embodiment in which the side wall H2A is protected by a reaction product generated through etching, focusing on the differences from the first, second, and third embodiments. FIGS. 17A and 17B are cross-sectional views illustrating a method of manufacturing a semiconductor device according to the fourth embodiment. FIGS. 18A and 18B are cross-sectional views illustrating the method of manufacturing the semiconductor device according to the fourth embodiment, subsequently to FIGS. 17A and 17B.

In the example illustrated in FIGS. 17A, 17B, 18A, and 18B, a second surface layer 12, which contains a reaction product P (FIG. 17A) generated through etching, is formed on the side wall H2A of the hole H2 during the etching of the processing target object 10 (FIG. 17B). After the second surface layer 12 is formed, the surface layer 11 is formed on the side wall H2A and the bottom surface H2B of the hole H2 (FIG. 18A). After the surface layer 11 is formed, etching is repeated (FIG. 18B).

According to the fourth embodiment, bowing can be more effectively prevented by protecting the side wall H2A with the surface layer 11 and the second surface layer 12.

In the above-mentioned embodiments, the stacked film 103, 104 is shown as an example of a stacked film of the processing target object 10. The processing target object 10 is not limited to including the stacked film 103, 104, and may include, for example, a silicon film or a carbon film. Further, in the above-mentioned embodiments, the memory hole H2 is shown as an example of the recess portion. The recess portion is not limited to the memory hole, and may be, for example, a via hole for embedding a via plug.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of manufacturing a semiconductor device using a semiconductor manufacturing apparatus, comprising:
forming a first surface layer on a recess portion of a processing target object, by supplying a first gas onto the processing target object while cooling the processing target object and without applying a high-frequency voltage to a processing chamber of the semiconductor manufacturing apparatus, wherein the first gas contains no halogens; and
etching the processing target object by supplying a second gas onto the processing target object while applying the high-frequency voltage to the processing chamber, wherein the second gas contains a halogen.

2. The method of manufacturing the semiconductor device according to claim 1, wherein the first gas has a higher condensation temperature than the second gas.

3. The method of manufacturing the semiconductor device according to claim 2, wherein the first surface layer is formed in a state where the processing target object has been cooled to a temperature equal to or lower than the condensation temperature of the first gas.

4. The method of manufacturing the semiconductor device according to claim 3, wherein the first surface layer is further formed in a state where the processing target object has been cooled to a temperature equal to or higher than the condensation temperature of the second gas.

5. The method of manufacturing the semiconductor device according to claim 1, wherein the pressure in the processing chamber when the first surface layer is formed is higher than the pressure in the processing chamber when the processing target object is etched.

6. The method of manufacturing the semiconductor device according to claim 1, wherein the first gas is an inorganic gas that contains no halogens.

7. The method of manufacturing the semiconductor device according to claim 6, wherein the inorganic gas is water vapor or hydrogen peroxide.

8. The method of manufacturing the semiconductor device according to claim 1, wherein the first gas is an organic gas that contains no halogens.

9. The method of manufacturing the semiconductor device according to claim 1, wherein the second gas contains a fluoride gas.

10. The method of manufacturing the semiconductor device according to claim 1, wherein the first surface layer is formed on a side wall of the recess portion.

11. The method of manufacturing the semiconductor device according to claim 10, wherein the first surface layer is also formed on a bottom surface of the recess portion.

12. The method of manufacturing the semiconductor device according to claim 11, further comprising:
removing the first surface layer formed on the bottom surface of the recess portion, between the forming of the first surface layer and the etching of the processing target object.

13. The method of manufacturing the semiconductor device according to claim 12, wherein the first surface layer formed on the bottom surface of the recess portion is removed by performing etching with plasma generated from a third gas.

14. The method of manufacturing the semiconductor device according to claim 10, wherein the first surface layer is formed on the side wall of the recess portion without being formed on the bottom surface of the recess portion.

15. The method of manufacturing the semiconductor device according to claim 11, wherein when the etching of the processing target object is performed, the side wall is protected from etching by the first surface layer formed on the side wall of the recess portion, and the first surface layer formed on the bottom surface of the recess portion promotes etching of the bottom surface of the recess portion.

16. The method of manufacturing the semiconductor device according to claim 15, wherein the etching of the processing target object is performed in a state where the first gas is added to the second gas.

17. The method of manufacturing the semiconductor device according to claim 16, wherein the first gas is continuously supplied during both the forming of the first surface layer and the etching of the processing target object.

18. The method of manufacturing the semiconductor device according to claim 10, wherein before the first surface layer is formed, a second surface layer is formed by etching of the processing target object on the side wall of the recess portion, the second surface layer containing a reaction product generated by the etching on the side wall of the recess portion.
